(19) United States
(12) Patent Application Publication
(10) Pub. No.: US 2025/0382493 A1
(43) Pub. Date: Dec. 18, 2025

(54) EPOXY RESIN COMPOSITION FOR ENCAPSULATING SEMICONDUCTOR DEVICE AND SEMICONDUCTOR DEVICE ENCAPSULATED USING THE SAME

(71) Applicant: SAMSUNG SDI CO., LTD., Yongin-si, Gyeonggi-do (KR)

(72) Inventor: Yong Yeop PARK, Suwon-si (KR)

(21) Appl. No.: 19/215,619

(22) Filed: May 22, 2025

(30) Foreign Application Priority Data
Jun. 14, 2024 (KR) 10-2024-0077638

(51) Int. Cl. C09D 163/00; C08G 59/22; C08G 59/24; C08G 59/28; C08K 3/36; C09D 7/61; H01L 23/29

(52) U.S. Cl. CPC C09D 163/00; C08G 59/226; C08G 59/245; C08G 59/28; C09D 7/61; H01L 23/295; C08K 3/36

(57) ABSTRACT

An epoxy resin composition for encapsulation of semiconductor devices and a semiconductor device encapsulated using the epoxy resin composition, the epoxy resin composition including an epoxy resin, a curing agent, inorganic filler, and a curing catalyst, wherein the epoxy resin includes at least one epoxy resin compound represented by Formula 1:

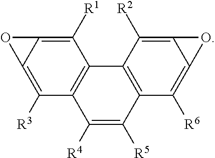

### CROSS-REFERENCE TO RELATED APPLICATION

The present application claims priority and the benefit of Korean Patent Application No. 10-2024-0077638, filed on Jun. 14, 2024 in the Korean Intellectual Property Office, the entire disclosure of which is incorporated herein by reference.

### 1. FIELD

Embodiments relate to an epoxy resin composition for encapsulation of semiconductor devices and a semiconductor device encapsulated using the same.

### 2. DESCRIPTION OF THE RELATED ART

A typical method of encapsulating semiconductor devices may involve dicing a wafer into individual chips, followed by individually packaging each chip. A process has been developed in which a wafer containing multiple chips may be processed for packaging before dicing into individual chips. In general, the former method may be called chip-scale packaging (CSP) and the latter process may be called wafer-level packaging (WLP).

### SUMMARY

Embodiments are directed to an epoxy resin composition for encapsulation of semiconductor devices, the epoxy resin composition including an epoxy resin, a curing agent, inorganic filler, and a curing catalyst, wherein the epoxy resin includes at least one epoxy resin compound represented by Formula 1:

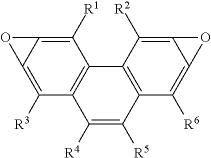

wherein R¹ to R⁶ are each independently hydrogen, a nitrogen atom-containing functional group, a substituted or unsubstituted C₁ to C₂₀ alkyl group, a substituted or unsubstituted C₆ to C₃₀ aryl group, a substituted or unsubstituted C₆ to C₃₀ aryloxy group, a substituted or unsubstituted C₃ to C₃₀ heteroaryl group, a substituted or unsubstituted C₃ to C₃₀ heterocycloalkyl group, a substituted or unsubstituted C₇ to C₃₀ arylalkyl group, or a substituted or unsubstituted C₁ to C₃₀ heteroalkyl group.

In Formula 1 R¹ to R⁶ may each be hydrogen.

In Formula 1 at least one of R¹ and R³ may be a substituted or unsubstituted C₁ to C₂₀ alkyl group, a substituted or unsubstituted C₆ to C₃₀ aryl group, an amino group, or an amine group.

In Formula 1 at least one of R² and R⁶ may be a substituted or unsubstituted C₁ to C₂₀ alkyl group, a substituted or unsubstituted C₆ to C₃₀ aryl group, an amino group, or an amine group.

In Formula 1 R⁴ and R⁵ may each be hydrogen.

The at least one epoxy resin compound represented by Formula 1 may include at least one compound represented by Formula 1-1 to 1-4,

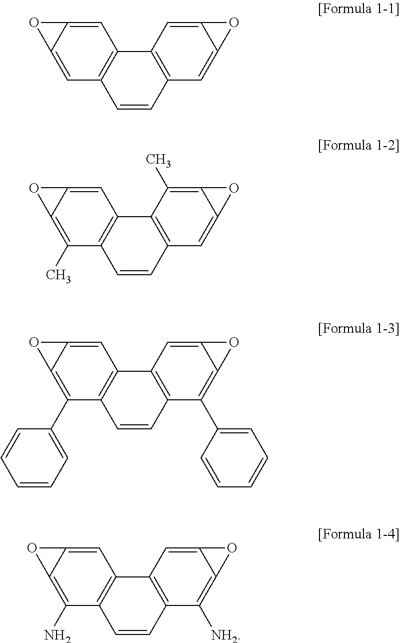 [SMILES: c1cc2cc3oc3cc2c2cc3oc3cc12 ; Cc1c2ccc3cc4oc4c(C)c3c2cc2oc12 ; c1ccc(-c2c3ccc4c(-c5ccccc5)c5oc5cc4c3cc3oc23)cc1 ; Nc1c2ccc3c(N)c4oc4cc3c2cc2oc12]

The at the at least one epoxy resin compound may be included in the epoxy resin composition in an amount of 0.1 wt % to 17 wt %, based on a total weight of the epoxy resin composition.

The inorganic filler may include silica.

The epoxy resin composition may include, based on a total weight of the epoxy resin composition, 2 wt % to 17 wt % of the epoxy resin, 0.5 wt % to 13 wt % of the curing agent, 50 wt % to 95 wt % of the inorganic filler, and 0.01 wt % to 5 wt % of the curing catalyst.

The embodiments may be realized by providing a semiconductor device encapsulated using the epoxy resin composition according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURES, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not an exclusive term, e.g., “A or B” would include A, B, or A and B.

As used herein to represent a specific numerical range, “X to Y” means “greater than or equal to X and less than or equal to Y”.

As used herein, the term “substituted” in the expression “substituted or unsubstituted” means that at least one hydrogen atom of a corresponding functional group is substituted with a hydroxyl group, an amino group, a nitro group, a cyano group, a C₁ to C₂₀ alkyl group, a C₁ to C₂₀ haloalkyl group, a C₆ to C₃₀ aryl group, a C₃ to C₃₀ heteroaryl group, a C₃ to C₁₀ cycloalkyl group, a C₃ to C₁₀ heterocycloalkyl group, a C₇ to C₃₀ arylalkyl group, or a C₁ to C₃₀ heteroalkyl group.

Herein, “hetero” may refer to nitrogen, oxygen, or sulfur.

Herein, unless otherwise stated, it may be assumed that a hydrogen atom is bonded to a chemical structure represented by a corresponding chemical formula.

In accordance with one aspect of the present disclosure, an epoxy resin composition for encapsulation of semiconductor devices may help minimize warpage and may help achieve high reliability due to good adhesion to a redistribution layer and low moisture absorption rate thereof. In an implementation, the epoxy resin composition for encapsulation of semiconductor devices may be prepared in solid particle form, thus providing high durability and ease of storage and use when used in wafer-level packaging applications.

The epoxy resin composition for encapsulation of semiconductor devices may include, e.g., an epoxy resin, a curing agent, an inorganic filler, or a curing catalyst, wherein the epoxy resin may include an epoxy resin represented by Formula 1. The epoxy resin represented by Formula 1 may help ensure that the epoxy resin composition provides the desired effects described above.

### Epoxy Resin

The epoxy resin may include at least one epoxy resin compound represented by Formula 1. The at least one epoxy resin compound represented by Formula 1 may help minimize warpage, improve adhesion to a redistribution layer, and help enable preparation of an epoxy resin composition in solid particle form, e.g., tablet form, for ease of storage and use.

In one embodiment, the epoxy resin represented by Formula 1 may easily achieve the desired effects described above if, e.g., silica is used as the inorganic filler.

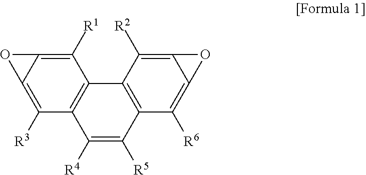

In Formula 1, R¹ to R⁶ may each independently be or include, e.g., hydrogen, a nitrogen atom-containing functional group, a substituted or unsubstituted C₁ to C₂₀ alkyl group, a substituted or unsubstituted C₆ to C₃₀ aryl group, a substituted or unsubstituted C₆ to C₃₀ aryloxy group, a substituted or unsubstituted C₃ to C₃₀ heteroaryl group, a substituted or unsubstituted C₃ to C₃₀ heterocycloalkyl group, a substituted or unsubstituted C₇ to C₃₀ arylalkyl group, or a substituted or unsubstituted C₁ to C₃₀ heteroalkyl group.

In one embodiment, the nitrogen atom-containing functional group may be, e.g., an isocyanate group (—N═C═O), a cyano group (—CN), a nitro group (—NO₂), an amino group, or an amine group (—NR⁷R⁸ wherein R⁷ and R⁸ may each independently be, e.g., hydrogen, a substituted or unsubstituted C₁ to C₁₀ aryl group, or a substituted or unsubstituted C₆ to C₁₀ aryl group).

In one embodiment, the C₆ to C₃₀ aryl group or the C₆ to C₃₀ aryloxy group may be, e.g., a monocyclic or polycyclic aryl group, e.g., a phenyl group, a biphenyl group, a naphthyl group, a naphthyloxy group, or an anthracenyl group.

In one embodiment, at least one of R¹ to R⁶ may be, e.g., a substituted or unsubstituted C₆ to C₃₀ aryl group or a nitrogen atom-containing functional group.

In one embodiment, in Formula 1, R¹ to R⁶ may be, e.g., hydrogen.

In one embodiment, in Formula 1, each of R⁴ and R⁵ may be, e.g., hydrogen.

In one embodiment, in Formula 1, at least one of R¹ and R³ may be a substituted or unsubstituted C₁ to C₂₀ alkyl group, a substituted or unsubstituted C₆ to C₃₀ aryl group, an amino group, or an amine group. In an implementation, at least one of R¹ and R³ may be an unsubstituted C₁ to C₁₀ alkyl group, an unsubstituted C₁ to C₅ alkyl group, an unsubstituted C₆ to C₂₀ aryl group, an unsubstituted C₆ to C₁₀ aryl group, or an NH₂ group.

In one embodiment, in Formula 1, at least one of R² and R⁶ may be, e.g., a substituted or unsubstituted C₁ to C₂₀ alkyl group, a substituted or unsubstituted C₆ to C₃₀ aryl group, an amino group, or an amine group. In an implementation, at least one of R² and R⁶ may be an unsubstituted C₁ to C₁₀ alkyl group, an unsubstituted C₁ to C₅ alkyl group, an unsubstituted C₆ to C₂₀ aryl group, an unsubstituted C₆ to C₁₀ aryl group, or an NH₂ group.

In an implementation, the at least one epoxy resin compound represented by Formula 1 may include, e.g., at least one compound represented by one of Formula 1-1 to Formula 1-4.

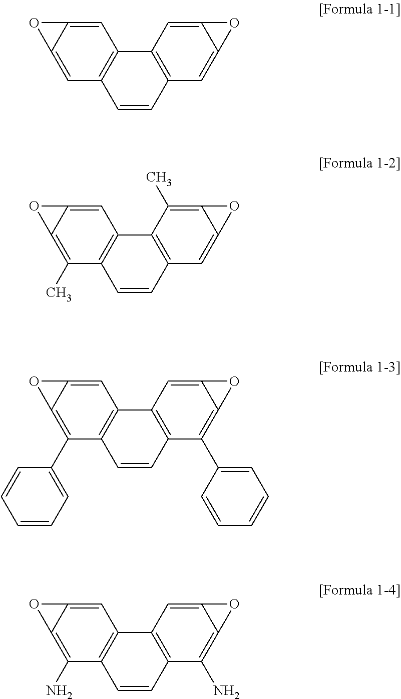 [SMILES: c1cc2cc3oc3cc2c2cc3oc3cc12 ; Cc1c2ccc3cc4oc4c(C)c3c2cc2oc12 ; c1ccc(-c2c3ccc4c(-c5ccccc5)c5oc5cc4c3cc3oc23)cc1 ; Nc1c2ccc3c(N)c4oc4cc3c2cc2oc12]

The epoxy resin composition may include one or more types of epoxy resin compounds represented by Formula 1. The at least one epoxy resin represented by Formula 1 may be included in the epoxy resin composition in an amount of 0.1 wt % to 17 wt %, e.g., 2 wt % to 17 wt % or 2 wt % to 10 wt %, based on a total weight of the epoxy resin composition. Maintaining the at least one epoxy resin represented by Formula 1 in these ranges may help ensure that the epoxy resin represented by Formula 1 may help improve heat dissipation capacity of the composition without sacrificing curability of the composition.

In one embodiment, the epoxy resin may include a compound represented by Formula 1-1 and another compound represented by one of Formula 1-2, Formula 1-3, or Formula 1-4 in a weight ratio of 1:1 to 1:10, e.g., 1:2 to 1:8. Maintaining the weight ratio within these ranges may help ensure that the epoxy resin composition can easily achieve the desired effects described above.

The epoxy resin compound represented by Formula 1 may be prepared by a suitable epoxy resin preparation with reference to Formula 1.

The epoxy resin may consist solely of epoxy resin compounds represented by Formula 1. In an implementation, the epoxy resin composition may further include an epoxy resin other than the at least one epoxy resin compound represented by Formula 1, without affecting the desired effects of the embodiments. For descriptive convenience, the at least one epoxy resin compound represented by Formula 1 will be referred to as a first epoxy resin, and the epoxy resin other than the epoxy resin represented by Formula 1 will be referred to as a second epoxy resin.

The second epoxy resin may be an epoxy resin compound containing at least two epoxy groups in a molecular structure thereof and may include, e.g., bisphenol A type epoxy resins, bisphenol F type epoxy resins, phenol novolac type epoxy resins, tert-butyl catechol type epoxy resins, naphthalene type epoxy resins, glycidyl amine type epoxy resins, cresol novolac type epoxy resins, biphenyl type epoxy resins, phenol aralkyl type epoxy resins, linear aliphatic epoxy resins, cycloaliphatic epoxy resins, heterocyclic epoxy resins, spirocyclic epoxy resins, cyclohexanedimethanol type epoxy resins, trimethylol type epoxy resins, halogenated epoxy resins, and the like. As the second epoxy resin, these epoxy resins may be used alone or as a mixture thereof.

The epoxy resin may be included in the epoxy resin composition in an amount of 2 wt % to 17 wt %, e.g., 2 wt % to 10 wt %, based on a total weight of the epoxy resin composition. Maintaining the amount of epoxy resin within these ranges may help ensure that the composition may secure curability.

### Curing Agent

The curing agent may include, e.g., polyfunctional phenol resins, phenol aralkyl type phenol resins, phenol novolac type phenol resins, Xylok type phenol resins, cresol novolac type phenol resins, naphthol type phenol resins, terpene type phenol resins, dicyclopentadiene phenol resins, novolac type phenol resins synthesized from bisphenol A and resol, polyhydric phenol compounds including, e.g., tris(hydroxyphenyl)methane, dihydroxybiphenyl, or the like, acid anhydrides including, e.g., maleic anhydride, phthalic anhydride, or the like, and aromatic amines including, e.g., metaphenylenediamine, diaminodiphenylmethane, diaminodiphenylsulfone, or the like. In an implementation, the curing agent may include, e.g., a Xylok type phenol resin or a phenol aralkyl type phenol resin.

The curing agent may be included in the epoxy resin composition in an amount of, e.g., 0.5 wt % to 13 wt %, based on a total weight of the epoxy resin composition. Maintaining the curing agent within this range may help ensure that the epoxy resin composition may secure curability.

### Inorganic Filler

The inorganic filler may serve to improve mechanical properties of the epoxy resin composition while reducing internal stress of the epoxy resin composition.

The inorganic filler may include, e.g., fused silica, crystalline silica, calcium carbonate, magnesium carbonate, alumina, magnesia, clay, talc, calcium silicate, titanium oxide, antimony oxide, and glass fiber.

In an implementation, the inorganic filler may include fused silica having a low coefficient of linear expansion to reduce internal stress of the epoxy resin composition. Here, the fused silica may refer to an amorphous silica having a true specific gravity of 2.3 or less and may include amorphous silica that may be prepared by melting crystalline silica or may be synthesized from various raw materials. Although the shape and particle size of the fused silica may not be particularly restricted, it may be desirable that a fused silica mixture including, e.g., 50 wt % to 99 wt % of spherical fused silica having an average particle diameter of 5 μm to 30 μm and 1 wt % to 50 wt % of spherical fused silica having an average particle diameter of 0.001 μm to 1 μm, all based on total weight of the fused silica mixture, be included in the inorganic filler in an amount of 40 wt % to 100 wt %, based on the total weight of the inorganic filler. In an implementation, the maximum particle diameter of the fused silica may be adjusted, e.g., to 45 μm, 55 μm, 75 μm, or the like, depending on the intended applications thereof.

The content of the inorganic filler in the composition may be varied depending on properties required for the composition, such as thermal conductivity, moldability, low stress, and strength at high temperature. In some embodiments, the inorganic filler may be included in the epoxy resin composition in an amount of 50 wt % to 95 wt %, e.g., 70 wt % to 95 wt %, 85 wt % to 95 wt %, based on a total weight of the epoxy resin composition. Maintaining the amount of inorganic filler in this range may help ensure that the epoxy resin composition may have good properties in terms of flame retardancy, fluidity, and reliability.

### Curing Catalyst

The curing catalyst may include, e.g., a tertiary amine compound, an organometallic compound, an organophosphorus compound, an imidazole compound, or a boron compound. The tertiary amine compound may include, e.g., benzyldimethylamine, triethanolamine, triethylenediamine, diethylaminoethanol, tri(dimethylaminomethyl)phenol, 2,2-(dimethylaminomethyl)phenol, 2,4,6-tris(diaminomethyl)phenol, tri-2-ethyl hexanoate, or the like. The organometallic compound may include, e.g., chromium acetylacetonate, zinc acetylacetonate, nickel acetylacetonate, or the like. The organophosphorus compound may include, e.g., triphenylphosphine, tris-4-methoxyphosphine, triphenylphosphine-triphenylborane, a triphenylphosphine-1,4-benzoquinone adduct, or the like. The imidazole compound may include, e.g., 2-methylimidazole, 2-phenylimidazole, 2-aminoimidazole, 2-methyl-1-vinylimidazole, 2-ethyl-4-methylimidazole, 2-heptadecyl imidazole, or the like. The boron compound may include, e.g., triphenylphosphine tetraphenyl borate, a tetraphenylboron salt, trifluoroborane-n-hexylamine, trifluoroborane monoethylamine, tetrafluoroborane triethylamine, tetrafluoroborane amine, or the like. In an implementation, 1,5-diazabicyclo[4.3.0]non-5-ene (DBN), 1,8-diazabicyclo[5.4.0]undec-7-ene (DBU), or a phenol novolac resin salt may be used as the curing catalyst.

The curing catalyst may be provided, e.g., in the form of an adduct prepared by pre-reacting the curing catalyst with the epoxy resin or the curing agent.

The curing catalyst may be included in the epoxy resin composition, e.g., in an amount of 0.01 wt % to 5 wt %, based on a total weight of the epoxy resin composition. Maintaining the amount of the curing catalyst in this range may help ensure that the curing catalyst may help promote curing of the composition without sacrificing fluidity of the composition.

The epoxy resin composition may further include suitable additives used in epoxy resin compositions for encapsulation of semiconductor devices. In some embodiments, the additives may include, e.g., a coupling agent, a release agent, a colorant, a stress relieving agent, a crosslinking enhancer, or a leveling agent.

The coupling agent may serve to increase interfacial strength between the epoxy resin and the inorganic filler through reaction with the epoxy resin and the inorganic filler and may include, e.g., a silane coupling agent. The silane coupling agent may include any silane coupling agent that may increase interfacial strength between the epoxy resin and the inorganic filler through reaction with the epoxy resin and the inorganic filler. The silane coupling agent may include, e.g., epoxysilane, aminosilane, ureidosilane, mercaptosilane, an alkylsilane, or the like. These coupling agents may be used alone or in combination thereof. The coupling agent may be included in the epoxy resin composition in an amount of 0.01 wt % to 5 wt %, e.g., 0.05 wt % to 3 wt %, based on a total weight of the epoxy resin composition. Maintaining the amount of coupling agent within these ranges may help ensure that a cured product of the epoxy resin composition may have enhanced strength.

The release agent may include, e.g., paraffin wax, ester wax, higher fatty acids, metal salts of higher fatty acids, natural fatty acids, and metal salts of natural fatty acids. The release agent may be included in the epoxy resin composition an amount of 0.1 wt % to 1 wt %, based on a total weight of the epoxy resin composition.

The colorant may include, e.g., carbon black. The colorant may be included in the epoxy resin composition in an amount of 0.1 wt % to 1 wt %, based on a total weight of the epoxy resin composition.

The stress relieving agent may include, e.g., modified silicone oils, silicone elastomers, silicone powders, and silicone resins. The stress relieving agent may be included in the epoxy resin composition in an amount of 2 wt % or less, e.g., 1 wt % or less or 0.1 wt % to 1 wt %, based on a total weight of the epoxy resin composition.

The additives may be included in the epoxy resin composition in an amount of 0.1 wt % to 5 wt %, e.g., 0.1 wt % to 3 wt %, based on a total weight of the epoxy resin composition.

The epoxy resin composition may be prepared, e.g., by uniformly mixing the aforementioned components in a Henschel mixer or a Lödige mixer, melt-kneading the mixture in a roll mill or a kneader at, e.g., 90° C. to 120° C., and subjecting the resulting product to cooling and pulverization.

In accordance with another aspect of the present disclosure, a semiconductor device may be encapsulated using the epoxy resin composition for encapsulation of semiconductor devices according to an embodiment. The semiconductor device may be encapsulated with the epoxy resin composition by any suitable method, such as transfer molding, injection molding, casting, or compression molding. In one embodiment, the semiconductor device may be encapsulated with the epoxy resin composition by low-pressure transfer molding. In another embodiment, the semiconductor device may be encapsulated with the epoxy resin composition by compression molding.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparative Example 1: Preparation of Epoxy Resin (a1)

A compound represented by Formula 2-1 was placed in 1,2-dichloroethane as a solvent, followed by reaction in the presence of an excess of hydrogen peroxide and a small quantity of molybdenum as catalysts under heating to 80° C. for 1 hour. The reaction product was cooled to ambient temperature, followed by removing a residue of the compound represented by Formula 2-1 using a rotary evaporator (bath temperature: 50° C., pressure: 30 mbar). The resulting compound was dissolved in toluene, followed by heating the reaction product to 80° C. The reaction product was filtered through a filter, followed by removing the remaining solvent using a rotary evaporator, thereby preparing an epoxy resin represented by Formula 1-1.

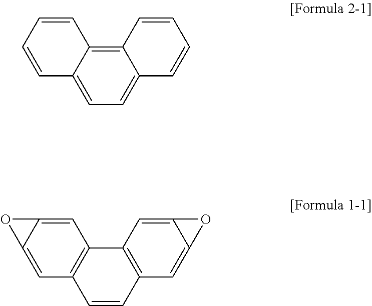

### Preparative Example 2: Preparation of Epoxy Resin (a2)

An epoxy resin represented by Formula 1-2 was prepared in the same manner as in Preparative Example 1 except that a compound represented by Formula 2-2 was used instead of the compound represented by Formula 2-1.

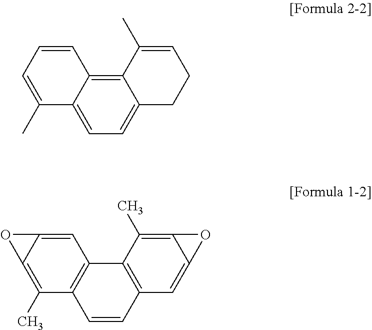

### Preparative Example 3: Preparation of Epoxy Resin (a3)

An epoxy resin represented by Formula 1-3 was prepared in the same manner as in Preparative Example 1 except that a compound represented by Formula 2-3 was used instead of the compound represented by Formula 2-1.

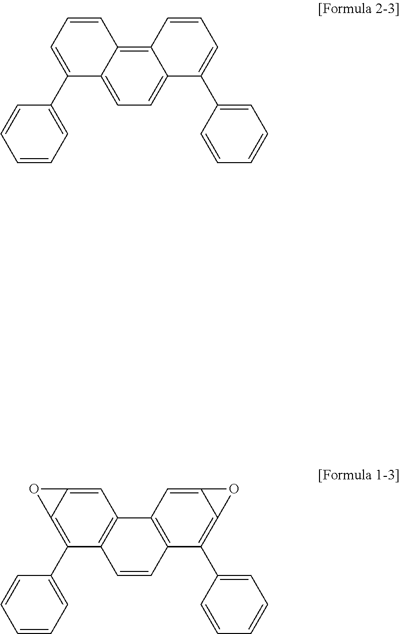

### Preparative Example 4: Preparation of Epoxy Resin (a4)

An epoxy resin represented by Formula 1-4 was prepared in the same manner as in Preparative Example 1 except that a compound represented by Formula 2-4 was used instead of the compound represented by Formula 2-1.

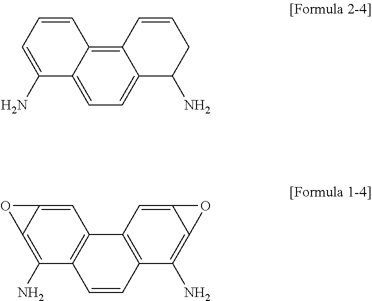 [SMILES: Nc1cccc2c3c(ccc12)C(N)CC=C3 ; Nc1c2ccc3c(N)c4oc4cc3c2cc2oc12]

Details of components used in the Examples and Comparative Examples were as follows:
(A) Epoxy resin
(a1) to (a4) Epoxy resins of Preparative Examples 1 to 4
(a5) A phenol aralkyl type epoxy resin (NC-3000, Nippon Kayaku Co., Ltd.)
(a6) A biphenyl type epoxy resin (YX-4000H, Mitsubishi Chemical Co., Ltd.)
(a7) A polyaromatic epoxy resin having an anthracene backbone (YX-8800, Mitsubishi Chemical Co., Ltd.)
(B) Curing agent
(b1) KPH-F3065 (Xylok type phenol resin, Kolon Chemical Co., Ltd.)
(b2) MEH-7851 (phenol aralkyl type phenol resin, Meiwa Chemical Co., Ltd.)
(C) Curing catalyst
(c1) Triphenyl phosphine (Hokko Chemical Co., Ltd.)
(c2) 1,4-benzoquinone (Sigma-Aldrich Chemical Co., Inc.)
(D) Inorganic filler: A mixture of spherical fused alumina having an average particle diameter (D₅₀) of 20 μm and spherical fused alumina having an average particle diameter (D₅₀) of 0.5 μm (weight ratio: 9:1)
(E) Coupling agent
(e1) Methyltrimethoxysilane (SZ-6070, Dow Corning Corporation)
(e2) KBM-573 (N-phenyl-3-aminopropyltrimethoxysilane, Shinetsu Chemical Co., Ltd.)
(F) Colorant: Carbon black (MA-600B, Mitsubishi Chemical Co., Ltd.)

### Example 1 to 5 and Comparative Examples 1 to 3

The aforementioned components were uniformly mixed in the amounts shown in Table 1 (unit: parts by weight) in a Henschel mixer (KSM-22, KEUM SUNG MACHINERY Co., Ltd.) at a temperature of 25° C. to 30° C. for 30 minutes. Thereafter, the mixture was subjected to melt-kneading in a continuous kneader at a temperature of up to 110° C. for 30 minutes, cooled to a temperature of 10° C. to 15° C., and pulverized, thereby preparing an epoxy resin composition for encapsulation of semiconductor devices. Thereafter, 4.5 g of the prepared epoxy resin composition was introduced into a tablet press and then pressed at a pressure of 12 tons, thereby preparing an encapsulation material in tablet form (outer diameter (D: 14 mm). In Table 1, “-” means that a corresponding component was not used.

Each of the epoxy resin compositions prepared in the Examples and Comparative Examples was evaluated as to the following properties. Results are shown in Table 1.

(1) Glass transition temperature (unit: ° C.) and coefficient of thermal expansion (unit: ppm/° C.): 4.2 g of each of the encapsulation compositions prepared in the Examples and Comparative Examples was subjected to transfer molding (molding temperature: 175° C., curing time: 120 seconds, transfer time: 14 seconds, transfer rate: 1.2 mm/see, clamp pressure: 40 tons, transfer pressure: 1 ton) to prepare a specimen, followed by measurement of the glass transition temperature and coefficients of thermal expansion (α1, α2) of the specimen using a thermomechanical analyzer (TMA) (Q400, TA Instruments, U. S.). A coefficient of thermal expansion measured in the temperature range before reaching the glass transition temperature of the specimen was defined as α1, and a coefficient of thermal expansion measured in the temperature range after reaching the glass transition temperature of the specimen was defined as α2.

(2) Warpage (unit: μm): An adhesive tape was attached to a carrier wafer (200 mm/8 inch or 300 mm/12 inch), followed by reconfiguration of single silicon chips on an upper surface of the carrier wafer with the adhesive tape attached thereto through a pick-and-place process. Thereafter, the carrier wafer was subjected to pre-baking treatment at 120° C. Thereafter, the carrier wafer was heated to a temperature of 120° C. to 170° C. and then each of the encapsulation compositions prepared in the Examples and Comparative Examples was applied to the carrier wafer, followed by cooling to ambient temperature, thereby forming a wafer-level encapsulation layer. Thereafter, the height and cross-section of the wafer were measured at 70,000 points on the wafer using a laser device (WDM-300, Lasertec Korea) and wafer-level warpage was calculated by the average of the measurement results.

Thereafter, the carrier wafer was heated to a temperature of 150° C. to 200° C. to separate the encapsulated semiconductor chips from the carrier wafer. Thereafter, a polybenzoxazole precursor solution was spin-coated on a molded wafer to form a redistribution layer and then the separated semiconductor chips were placed on the redistribution layer, followed by UV curing. Thereafter, the molded wafer was diced into individual semiconductor packages. Warpage of the obtained individual semiconductor packages was measured by profile analysis in accordance with JESD22-B112 using a shadow moiré system (IPO, Akrometrix, LLC, U.S.)

(3) Moisture absorption rate (unit: %): A test specimen was prepared using each of the encapsulation compositions of the Examples and Comparative Examples. Specifically, the test specimen was prepared by preparing a disc-shaped cured specimen (diameter: 5 cm, thickness: 5 mm) using a 30-ton press molding machine, followed by post-mold cure in a drying oven at 175° C. for 2 hours. After the initial weight of the test specimen was measured to the nearest 0.001 g, the test specimen was placed in a chamber of a pressure cooking tester (PCT) (EHS-211MD, ESPEC Corp., U.S.) and exposed to 120° C., 2 atm, and 100% RH for 24 hours, followed by measuring the weight of the specimen to the nearest 0.001 g to calculate moisture absorption rate of the specimen. The moisture absorption rate was determined by the average of three measurement results.

(4) Adhesive strength (unit: kgf): After plasma treatment of a Ni metal plate (size: 35 mm×35 mm×2 mm (length×width×thickness)), a polybenzoxazole (PBO)-based liquid type redistribution layer (RDL layer) was deposited to a thickness of 15 μm to 20 μm on the Ni metal plate by spin coating, followed by curing at 200° C., thereby preparing a substrate with the RDL layer formed thereon. Each of the encapsulation compositions of the Examples and Comparative Examples was deposited on the substrate by molding under conditions of a mold temperature of 175° C., a transfer pressure of 9 MPa, a transfer rate of 1 mm/sec, and a curing time of 90 seconds, thereby obtaining a cured specimen, which, in turn, was subjected to post-mold cure (PMC) in an oven at 175° C. for 4 hours. Thereafter, the presence of cracks in a semiconductor package was evaluated using a scanning acoustic microscope (C-SAM) (a device that determines the presence of delamination using sound waves, Sonix Technology Cp., Ltd.) and tensile strength (kgf) of the specimen was measured after pre-conditioning treatment in which a process of leaving the package at 60° C. and 60% RH for 120 hours, followed by TR reflow at 260° C. for 30 seconds was repeated three times. Here, the contact area of the epoxy resin composition with the substrate was 1 cm×1 cm, and the tensile test was conducted on three specimens for each measurement using a Universal Testing Machine (UTM). The tensile strength was calculated by the average of the measurement results,

TABLE 1

| | | Example | Example | Example | Example | Example | Comparative | Comparative | Comparative |
|---|---|---|---|---|---|---|---|---|---|
| | | 1 | 2 | 3 | 4 | 5 | Example 1 | Example 2 | Example 3 |
| (A) | (a1) | 8 | — | — | — | 2 | — | — | — |
| | (a2) | — | 8 | — | — | 2 | — | — | — |
| | (a3) | — | — | 8 | — | 2 | — | — | — |
| | (a4) | — | — | — | 8 | 2 | — | — | — |
| | (a5) | — | — | — | — | — | 5 | 3.5 | — |
| | (a6) | — | — | — | — | — | 1.5 | 3 | — |
| | (a7) | — | — | — | — | — | — | — | 8 |
| (B) | (b1) | 0.4 | 0.4 | 0.4 | 0.4 | 0.5 | 1 | 0.5 | 0.4 |
| | (b2) | 0.6 | 0.6 | 0.6 | 0.6 | 0.5 | 1.5 | 2 | 0.6 |
| (C) | (c1) | 0.2 | 0.2 | 0.2 | 0.2 | 0.1 | 0.2 | 0.1 | 0.2 |
| | (c2) | — | — | — | — | 0.1 | — | 0.1 | — |
| (D) | | 90 | 90 | 90 | 90 | 90 | 90 | 90 | 90 |
| (E) | (e1) | 0.1 | 0.1 | 0.1 | 0.1 | 0.1 | 0.1 | 0.1 | 0.1 |
| | (e2) | 0.2 | 0.2 | 0.2 | 0.2 | 0.2 | 0.2 | 0.2 | 0.2 |
| (F) | | 0.5 | 0.5 | 0.5 | 0.5 | 0.5 | 0.5 | 0.5 | 0.5 |
| Glass transition | | 188 | 183 | 179 | 175 | 175 | 160 | 175 | 173 |
| temperature | | | | | | | | | |
| Coefficient | α1 | 4.3 | 4.7 | 5.0 | 5.6 | 6.1 | 10.8 | 11 | 10.2 |
| of thermal | α2 | 28 | 30 | 52 | 34 | 38 | 38 | 42 | 37 |
| expansion | | | | | | | | | |
| Warpage | Wafer | 112 | 129 | 158 | 193 | 286 | 842 | 636 | 753 |
| | level | | | | | | | | |
| | Individual | 63 | 71 | 76 | 75 | 86 | 128 | 121 | 115 |
| | package | | | | | | | | |

| | | | | | | | | |
|---|---|---|---|---|---|---|---|---|
| Moisture | 0.12 | 0.15 | 0.16 | 0.18 | 0.20 | 0.97 | 0.83 | 0.78 |
| absorption rate | | | | | | | | |
| Adhesive | 67 | 65 | 61 | 63 | 66 | 32 | 38 | 35 |
| strength | | | | | | | | |

As can be seen from Table 1, the epoxy resin compositions for encapsulation of semiconductor devices according to the Examples could minimize warpage, achieve high reliability due to good adhesion to the redistribution layer and low moisture absorption thereof, and achieve high durability if used in wafer-level packaging. In addition, the epoxy resin compositions of the Examples could be prepared in solid particle form due to low moisture absorption rate thereof, thus providing ease of storage and use.

Conversely, the epoxy resin compositions of the Comparative Examples failed to provide the desirable effects described in the present disclosure.

By way of summation and review, wafer-level packaging may provide advantages over chip-scale packaging (CSP), e.g., simpler processes, reduced package thickness, and reduced semiconductor footprints. However, compared to chip-scale packaging in which each chip may be individually encapsulated, in wafer-level packaging, an encapsulation film may be formed over a large area, which may result in warpage due to thermal expansion mismatch between a wafer and an encapsulation material. Such warpage may affect the yield rate of subsequent processes and wafer handling. In addition, liquid type epoxy or silicone resins may be commonly used as an encapsulation material in wafer-level packaging. However, such encapsulation materials may be difficult to store due to poor storage stability thereof and cannot be re-stored after aging. Additionally, if the encapsulation materials are used in thin wafer-level packaging applications, low filler content thereof may compromise durability and reliability.

It is an aspect of the present disclosure provide an epoxy resin composition for encapsulation of semiconductor devices that may minimize warpage and may achieve high reliability due to good adhesion to a redistribution layer and low moisture absorption rate thereof.

It is another aspect of the present disclosure to provide an epoxy resin composition for encapsulation of semiconductor devices that may be prepared in solid particle form, thus providing high durability and ease of storage and use if used in wafer level packaging applications.

In accordance with an embodiment, an epoxy resin composition for encapsulation of semiconductor devices may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An epoxy resin composition for encapsulation of semiconductor devices, the epoxy resin composition comprising:
an epoxy resin,
a curing agent,
an inorganic filler, and
a curing catalyst,
wherein the epoxy resin includes at least one epoxy resin compound represented by Formula 1: 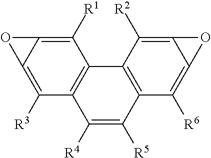
wherein R¹ to R⁶ are each independently hydrogen, a nitrogen atom-containing functional group, a substituted or unsubstituted C₁ to C₂₀ alkyl group, a substituted or unsubstituted C₆ to C₃₀ aryl group, a substituted or unsubstituted C₆ to C₃₀ aryloxy group, a substituted or unsubstituted C₃ to C₃₀ heteroaryl group, a substituted or unsubstituted C₃ to C₃₀ heterocycloalkyl group, a substituted or unsubstituted C₇ to C₃₀ arylalkyl group, or a substituted or unsubstituted C₁ to C₃₀ heteroalkyl group.

2. The epoxy resin composition as claimed in claim 1, wherein in Formula 1 R¹ to R⁶ are each hydrogen.

3. The epoxy resin composition as claimed in claim 1, wherein in Formula 1 at least one of R¹ and R³ is a substituted or unsubstituted C₁ to C₂₀ alkyl group, a substituted or unsubstituted C₆ to C₃₀ aryl group, an amino group, or an amine group.

4. The epoxy resin composition as claimed in claim 1, wherein in Formula 1 at least one of R² and R⁶ is a substituted or unsubstituted C₁ to C₂₀ alkyl group, a substituted or unsubstituted C₆ to C₃₀ aryl group, an amino group, or an amine group.

5. The epoxy resin composition as claimed in claim 1, wherein in Formula 1 R⁴ and R⁵ are each hydrogen.

6. The epoxy resin composition as claimed in claim 1, wherein the at least one epoxy resin compound represented by Formula 1 includes at least one compound represented by Formula 1-1 to 1-4,

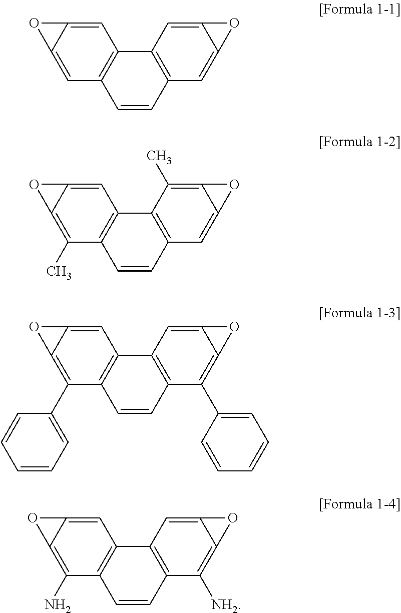

7. The epoxy resin composition as claimed in claim 1, wherein the at the at least one epoxy resin compound is included in the epoxy resin composition in an amount of 0.1 wt % to 17 wt %, based on a total weight of the epoxy resin composition.

8. The epoxy resin composition as claimed in claim 1, wherein the inorganic filler includes silica.

9. The epoxy resin composition as claimed in claim 1, wherein the epoxy resin composition includes, based on a total weight of the epoxy resin composition,
2 wt % to 17 wt % of the epoxy resin,
0.5 wt % to 13 wt % of the curing agent,
50 wt % to 95 wt % of the inorganic filler, and
0.01 wt % to 5 wt % of the curing catalyst.

10. A semiconductor device, the semiconductor device encapsulated using the epoxy resin composition as claimed in claim 1.

11. The semiconductor device as claimed in claim 10, wherein in Formula 1, R¹ to R⁶ are hydrogen.

12. The semiconductor device as claimed in claim 10, wherein in Formula 1 at least one of R¹ and R³ is a substituted or unsubstituted C₁ to C₂₀ alkyl group, a substituted or unsubstituted C₆ to C₃₀ aryl group, an amino group, or an amine group.

13. The semiconductor device as claimed in claim 10, wherein in Formula 1 at least one of R² and R⁶ is a substituted or unsubstituted C₁ to C₂₀ alkyl group, a substituted or unsubstituted C₆ to C₃₀ aryl group, an amino group, or an amine group.

14. The semiconductor device as claimed in claim 10, wherein in Formula 1 R⁴ and R⁵ are hydrogen.

15. The semiconductor device as claimed in claim 10, wherein the at least one epoxy resin compound includes at least one compound represented by one of Formula 1-1 to 1-4,

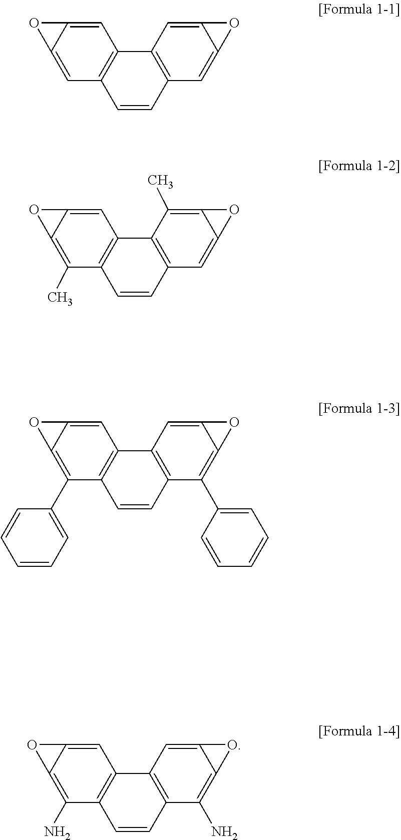 [SMILES: c1cc2cc3oc3cc2c2cc3oc3cc12 ; Cc1c2ccc3cc4oc4c(C)c3c2cc2oc12 ; c1ccc(-c2c3ccc4c(-c5ccccc5)c5oc5cc4c3cc3oc23)cc1 ; Nc1c2ccc3c(N)c4oc4cc3c2cc2oc12]

16. The semiconductor device as claimed in claim 10, wherein the at least one epoxy resin compound is included in the epoxy resin composition in an amount of 0.1 wt % to 17 wt %, based on a total weight of the epoxy resin composition.

17. The semiconductor device as claimed in claim 10, wherein the inorganic filler includes silica.

18. The semiconductor device as claimed in claim 10, wherein the epoxy resin composition includes, based on a total weight of the epoxy resin composition,
2 wt % to 17 wt % of the epoxy resin,
0.5 wt % to 13 wt % of the curing agent,
50 wt % to 95 wt % of the inorganic filler, and
0.01 wt % to 5 wt % of the curing catalyst.
